(19) United States
(12) Patent Application Publication
(10) Pub. No.: US 2006/0251975 A1
(43) Pub. Date: Nov. 9, 2006

(54) System and method for retrieving radiographic images

(75) Inventors: Arvind R. Taranath, Glenview, IL (US); Jeff I. Chu, Buffalo Grove, IL (US); Shrikant Deshpande, Glendale Heights, IL (US)

Correspondence Address: MCANDREWS HELD & MALLOY, LTD, 500 WEST MADISON STREET, SUITE 3400, CHICAGO, IL, 60661, US

(73) Assignee: General Electric Company

(21) Appl. No.: 11/121,197

(22) Filed: May 3, 2005

(51) Int. Cl. G03F 1/00

(52) U.S. Cl. 430/7

(57) ABSTRACT

Certain embodiments of the present invention provide a method of retrieving radiographic images including interfacing with a storage system containing radiographic images. Some of the radiographic images have data representative of an image modality. A method further includes determining at least one filter corresponding to a filter modality. Each filter may be independently determinable from other filters. Additionally, a method includes pre-fetching at least one radiographic image using the filter, wherein the image modality of the at least one radiographic image corresponds to the filter modality.

### BACKGROUND OF THE INVENTION

Embodiments of the present system and method relate generally to electronic communications in a healthcare setting. Particularly, certain embodiments relate to pre-fetching radiographic studies and images according to clinical relevance of the studies and images.

Clinics, hospitals, and other healthcare facilities have come to rely more and more on computers over the last several decades. In particular, healthcare facilities employ certain types of digital diagnostic imaging modalities, such as computed tomography (CT), magnetic resonance imaging (MRI), ultrasound imaging, and X-ray imaging. Each digital diagnostic imaging modality may generate images with formats that differ from other modalities. In response to the problem of different image formats, The American College of Radiology (ACR) and the National Electrical Manufacturers Association (NEMA) formed a joint committee in 1983 to develop a standard image format. This standard, eventually known as Digital Imaging and Communications in Medicine (DICOM): 1) promoted communication of digital image information, regardless of device manufacturer; 2) facilitated the development and expansion of Picture Archiving and Communication Systems (PACS) that may also interface with other systems of healthcare information; and 3) allowed for the creation of diagnostic information data bases that may be queried by a wide variety of devices distributed geographically.

Recent enhancements in DICOM have made the standard more flexible. For example, DICOM is now applicable to a network environment, where the initial imaging format standards were applicable only to a point-to-point environment. This enhancement is possible because DICOM now supports operation through the industry standard networking protocol known as TCP/IP. In another enhancement, DICOM specifies how devices claiming conformance to the standard will react to the exchange of both commands and data. In doing so, DICOM specifies the semantics of commands and associated data.

Importantly, DICOM introduces explicit information objects, which are elements used in an object-oriented database management environment in contrast with a relational database management environment. The information objects are used not only for image data such as raw image files, graphics, and waveforms, but also for administrative data to be used for creating reports or output printing. For information objects, DICOM specifies an established technique for uniquely identifying any information object. The technique facilitates unambiguous definitions of relationships between objects as they are used throughout a network.

Using DICOM standards, radiographic evidence documents (including images, reports, PDF files etc.) may be stored electronically. Generally speaking, there may be two types of storage systems used in PACS: (1) on-line storage systems that may have fast and relatively expensive storage media, like hard drives attached to a computer, and (2) long-term archiving systems that offer large amounts of data storage at relatively lower cost but with somewhat slower data access times.

On-line storage data may be immediately accessible to users while data stored in long-term archives may have to be retrieved onto the on-line storage before access by a user. As on-line storage fills up, data may be moved to the long-term archive to make room for new data. PACS manages data movements between the two types of storage systems.

Health care facilities may retain relatively old studies. Data retention, or information lifecycle management, may be required by government regulations or by clinical needs. For example, data may be retained to provide historical medical evidence to assist clinicians who make diagnoses and decisions. PACS may be implemented to manage the archiving of studies for information lifecycle management. Over time, information lifecycle management may result in a large accumulation of data. Consequently, long-term archiving may be a more cost-effective solution for information lifecycle management data retention.

Often, radiologists or other health care imaging specialists may wish to view historical studies to assist diagnoses of current patients. For example, when diagnosing a patient's injured leg, it may be useful for a radiologist to view historical images of the patient's leg. If a clinically relevant historical study is not stored in a fast-access on-line storage medium, the radiologist must wait for the retrieval of the study from a slower long-term archive. Frequent waiting drives up healthcare costs. Additionally, it may not be cost-effective to maintain historical studies and images in on-line storage systems. Therefore, it may be necessary to move historical studies and images between on-line storage systems and long-term archive systems to improve efficiency and reduce costs.

A system for retrieving historical radiographic studies and images assists a health care professional to review historical studies and images that are clinically relevant to the present diagnosis. One method currently employed to assist in efficient retrieval of clinically relevant historical images is called pre-fetching. Current pre-fetching methods may assess what studies are scheduled in the future, and then retrieve clinically relevant studies from an archive in advance of the scheduled study. For example a pre-fetching method may account for radiological studies scheduled for the next day. Then, a pre-fetching method may predict which historic studies are clinically relevant to scheduled studies. Any clinically relevant studies and images may be retrieved from a long-term archive into short-term storage. Pre-fetching is normally an automated activity. For example, pre-fetching may be a nightly event covering all studies scheduled for the next day. A pre-fetching method may be implemented by PACS.

Pre-fetching may improve the efficiency of a health care facility's computer system. For example, DICOM searches may be resource-intensive. By scheduling pre-fetching during off-peak hours, system resources may be efficiently managed. Pre-fetching may also improve the efficiency of radiologists and other health care professionals. Clinically relevant studies and images that have been pre-fetched may be accessed by system users more quickly. If clinically relevant historical studies have been pre-fetched into short-term storage, then a radiologist need not waste time fetching studies at the time of diagnosing new studies. Consequently, flexibility, functionality, and accuracy are primary design goals for pre-fetching methods. Inflexible, inaccurate pre-fetching methods create a drag on computer system performance, and on efficient time use for health care professionals.

Pre-fetching techniques may retrieve historic studies for a given patient based on additional filtering criteria. Pre-fetching may employ a filter including a number of subfilters. For example, current pre-fetch filters may include only one of the following subfilters: all studies in the last N months; a number N1 of the newest studies; a number N2 of the oldest studies; a number N1 of the newest studies of the same modality as the current scheduled study; a number N2 of the oldest studies of the same modality as the current scheduled study; a number N1 of the newest studies of the same body part as the current scheduled study; a number N2 of the oldest studies of the same body part as the current scheduled study.

Current pre-fetching techniques work well in health care facilities that have a few types of modalities and archives with only a few years of electronic image data. However, PACS archives are tending to become more complicated. Radiology departments may grow more diverse. New modalities are introduced over time, while older modalities must be supported. Additionally, archives are accumulating many more years of digital studies and images.

In light of the evolution of many health care imaging archives, current pre-fetch techniques may be limited. For example, many older studies may not be clinically relevant when reading new studies. The presence of older, irrelevant studies in a long-term archive may distort pre-fetch selections. Additionally, the presence of an increasing number of modalities may impede the efficacy of current pre-fetching techniques.

Generally, current pre-fetch filters are applicable system-wide for all modalities. In other words, current systems do not allow for each modality to have an associated filter. Current filters may be both over-inclusive (in that they retrieve too many studies and images) and under-inclusive (in that they do not accurately select clinically relevant historical records). For example, a pre-fetch filter may be configured to select images for a given patient generated within the last nine months. Images of all modalities generated in the last nine months would be fetched. The fetched images may include, for example, CT scan studies, even though the radiology department has only scheduled X-ray imaging for the patient. The fetched CT scan studies may be irrelevant to diagnosing the patient's X-ray image. This fetch is over-inclusive.

As another example, a pre-fetch filter may be configured to retrieve the 2 most recent studies for the patient. A pre-fetch retrieving the last 2 studies may be useful if the patient has a knee problem, and the radiologist only needs to view the most recent studies and images to make the present diagnosis. However, if the patient requires mammography, it may be helpful for the clinician to view mammographic studies and images spanning over the life of the patient. Therefore, a pre-fetch that retrieves only the last 2 studies may be useful for diagnosing a patient's knee, but this fetch will omit potentially relevant mammographic studies and images. This fetch is under-inclusive for mammography diagnosis.

Thus, there is a need for pre-fetching techniques that better accommodate the needs of health care professionals. There is a need for pre-fetching techniques that more accurately retrieve clinically relevant historical studies and images. There is a need for pre-fetching techniques that consume less computer system resources and bandwidth. There is a need for pre-fetching techniques with increased flexibility, functionality, and accuracy. There is a need for pre-fetching techniques that allow health care professionals to spend less valuable time retrieving records.

### BRIEF SUMMARY OF THE INVENTION

Certain embodiments of the present invention provide a method of retrieving radiographic images including interfacing with a storage system containing radiographic images. Some of the radiographic images have data representative of an image modality. The method further includes determining at least one filter corresponding to a filter modality. Each filter may be independently determinable from other filters. Additionally, the method includes pre-fetching at least one radiographic image using the filter, wherein the image modality of the at least one radiographic image corresponds to the filter modality. In an embodiment, the at least one filter comprises at least one subfilter capable of differentiating the radiographic images based at least in part on attributes of the radiographic images. In an embodiment the at least one subfilter may be independently determinable from at least one other subfilter. In an embodiment, the database comprises a long-term storage system. In an embodiment, a picture archiving and communication system (PACS) facilitates at least one of the interfacing, determining, and pre-fetching steps of the method. In an embodiment, more than one of the filters correspond to a filter modality. Each of the filters may be independently determinable from other of the filters. In an embodiment, the at least one filter may be determined to differentiate clinically relevant images in the storage system.

Certain embodiments of the present invention provide a system for gathering radiographic images comprising an interface to an archive including images, at least some of the images including information representative of a modality. The system also includes at least one filter capable of facilitating a selection images corresponding to the modality. The at least one filter may be independently configurable from other filters. In an embodiment, at least one subfilter corresponds to attributes of the images, and the at least one filter may facilitate a selection of images corresponding to the attributes of the images. In an embodiment, the at least one subfilter may be independently configurable from other subfilters. In an embodiment, a PACS may facilitate configuring the at least one filter. In an embodiment, a PACS may facilitate selecting the images from the archive. In an embodiment, the system includes an on-line image storage capable of short-term storage of selected said images. In an embodiment, the at least one filter may be automatedly used to select said images.

Certain embodiments of the present invention provide a computer readable storage medium including a set of instructions for a computer, the set of instructions comprising an interfacing routine for communicating with a storage system containing images, some of the images comprising data representative of a modality. The set of instructions further includes a filter recall routine for recalling at least one filter having parameters independently configurable from the parameters of other at least one filter. Additionally, the set of instructions comprises a pre-fetching routine for retrieving the images from the storage system based at least in part on the modality using the at least one filter. In an embodiment, the set of instructions further includes a scheduling routine for automatedly calling the pre-fetching routine. In an embodiment, a PACS facilitates execution of at least one of the interfacing, filter storage, and pre-fetching routines. In an embodiment, the storage system includes a long-term storage system. In an embodiment, the parameters include at least one of modality, procedure, anatomy, reason for procedure, date, significance, and physician. In an embodiment, the set of instructions comprises a filter configuration routine for independently configuring the at least one filter.

### BRIEF DESCRIPTION OF SEVERAL VIEWS OF THE DRAWINGS

FIG. 1 illustrates system components in a system employing pre-fetching techniques in accordance with an embodiment of the present invention.

FIG. 2 illustrates a flow diagram of a method for retrieving radiographic images in accordance with an embodiment of the present invention.

FIG. 3A shows a table representing examples of subfilters and parameters that may be available when determining a pre-fetch filter in accordance with an embodiment of the present invention.

FIGS. 3B and 3C show examples of potential configurations of subfilters and parameters in pre-fetch filters in accordance with embodiments of the present invention.

### DETAILED DESCRIPTION OF THE INVENTION

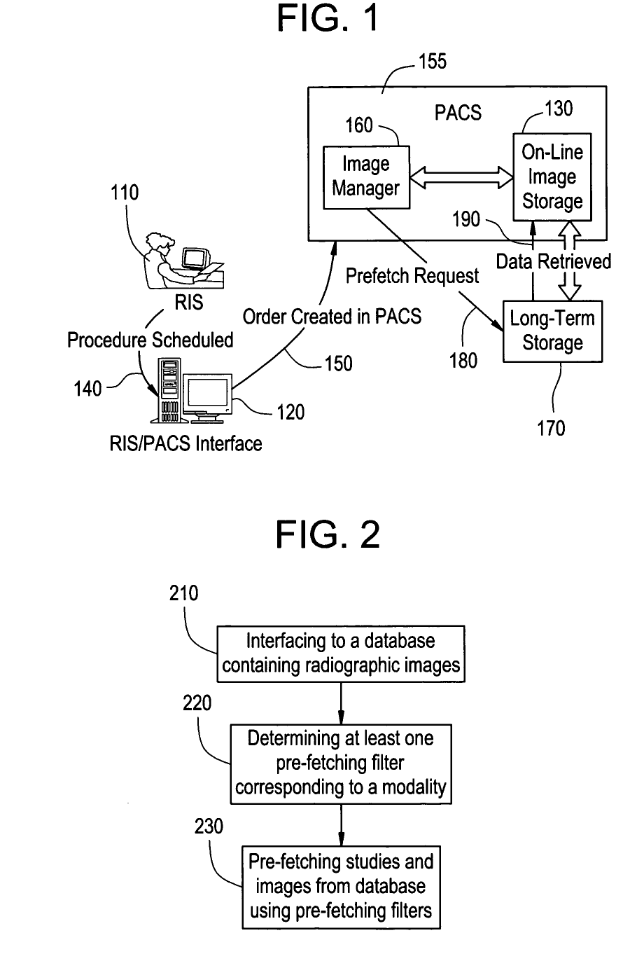

FIG. 1 illustrates a system 100 for image data pre-fetching used in accordance with an embodiment of the present invention. The system 100 includes a radiology information system (RIS) 110; a picture archiving and communication system (PACS) 155; a RIS/PACS interface 120; an image manager 160; an on-line image storage system 130; a long-term storage system 170. The components of the system 100 may be implemented in software and/or in hardware, for example. The components of the system 100 may be implemented separately and/or integrated in various forms. In certain embodiments, the system 100 may include a hospital information system (HIS), clinical information system (CIS), and cardiovascular information system (CVIS), library information system (LIS), and electronic medical record (EMR) system in addition to or in place of the RIS 110 and/or PACS 155.

Information regarding a scheduled procedure 140 may be communicated from the RIS 110 to a RIS/PACS interface 120. The RIS/PACS interface 120 may create an order 150, and communicate the order 150 with a PACS 155. The order 150 may include information representing the scheduled procedure 140. The PACS 155 may recode one or more orders 150, for example.

The PACS 155 may include the image manager 160 and the on-line image storage system 130. The order 150 may be received by the image manager 160. The image manager may communicate a prefetch request 180 to the long-term storage system 170 or other storage system or library, which may, in turn, retrieve studies and images and communicate retrieved data 190 to the on-line storage system 130. Various alternative embodiments for a system employing pre-fetching techniques are readily understood by those skilled in the art. For instance, the retrieved data 190 may be communicated from the long-term storage system to the image manager 160, which may, in turn, communicate the retrieved data 160 to the on-line storage system 130. In an embodiment, the image manager 160 includes one or more filters governing prefetch of image data, for example.

Each archived image or study may have one or more associated attributes. Attributes may be information describing the data in the image and study. Attributes may represent, for example, a date of the study, a physician who reported the study, a size of the study, a patient in the study, an anatomy of the study, and a modality of the study. The DICOM or other similar standard defines a wide range of attributes that may be associated with historical radiographic studies and images.

In an embodiment, the system 100 may be used to configure pre-fetching options and filters for multiple image modalities. Pre-fetching options and filters may be configured to apply for one or more modalities, for example. In an embodiment, pre-fetching for a modality may be configured using one or more filters. Filters used to select historical studies of a patient with respect to a new study may include: 1) a procedure type is the same as the new study or is in a set {P1, P2, etc.}; 2) an imaging modality is the same as the new study or is in a set {M1, M2, etc.}; 3) an anatomy is the same as the new study; 4) a reason for a procedure is the same as the new study; 5) a study date is not older than a date D; 6) a physician reporting a study is in a set {PN1, PN2, etc.}; and/or 7) all studies or a newest N1 plus an oldest N2 studies, for example. In an embodiment, such filters may be used in conjunction with and/or in place of system-wide filters such as all studies in the last N months; a number N1 of the newest studies; a number N2 of the oldest studies; a number N1 of the newest studies of the same modality as the current scheduled study; a number N2 of the oldest studies of the same modality as the current scheduled study; a number N1 of the newest studies of the same body part as the current scheduled study; and/or a number N2 of the oldest studies of the same body part as the current scheduled study. In an embodiment, a modality type may set values of configuration variables, such as P1, P2, M1, M2, D, PN1, PN2, N1, and/or N2.

In an embodiment, a user may mark a study as significant or un-relevant, for example. Filters may then be further modified based on significance marking of studies. In an embodiment, a significant study that satisfies the procedure type, modality, anatomy, reporting physician, and reason filters is selected for fetching, regardless of study date. However, a study marked un-relevant is not selected.

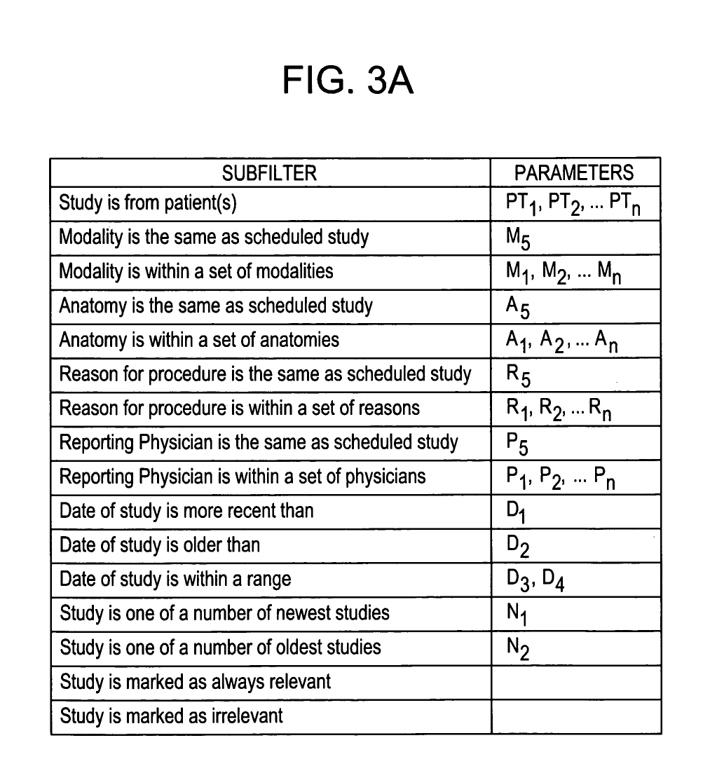

FIG. 2 illustrates a flow diagram of a method for retrieving radiographic images in accordance with an embodiment of the present invention. First, at step 210, a database containing radiographic images is interfaced. At step 220, a pre-fetching filter may be determined corresponding to a modality, such as Digital X-Ray. In an embodiment, more than one filter may be determined at step 220. For example, a filter may be determined for each modality type. If X-Ray and CT scan modalities are available, then two filters may be determined. The PACS 155 may assist in configuring and determining the filters for use during pre-fetching.

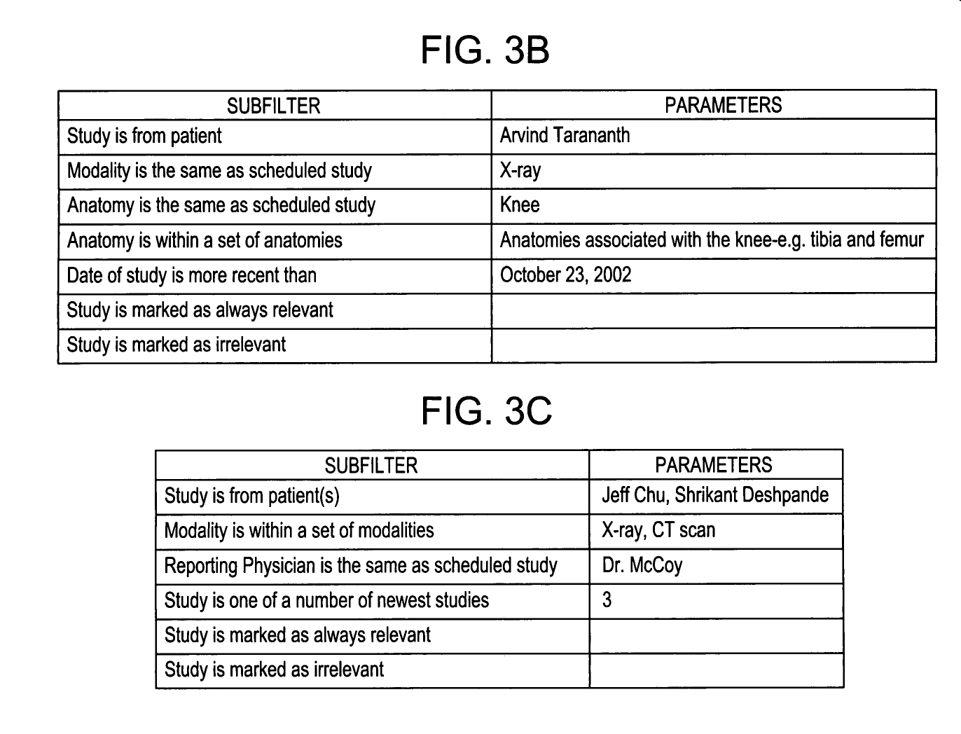

Determining a pre-fetch filter may involve selecting and configuring a number of subfilters and parameters. For example, FIG. 3A shows a table representing examples of subfilters and parameters that may be available when determining a pre-fetch filter. Each subfilter may be individually enabled or disabled. Each enabled subfilter may have corresponding parameters. Subfilters may accept one parameter or a plurality of parameters. A set of subfilter and parameter choices are designed to improve functionality, flexibility, and accuracy for pre-fetching. Those with ordinary skill in the art may appreciate that certain combinations of subfilters may inefficiently consume system resources. Therefore, certain combinations of subfilters and parameters may be disabled or disfavored when configuring pre-fetch filters. Generally speaking, the decision to limit certain combinations of subfilters and parameters represents a balancing between functionality and efficiency. By designing flexibility into pre-fetching, functionality and efficiency may be more sensitively balanced.

In an embodiment, some subfilters may not have associated parameters. For example, the subfilters shown in FIG. 3A for “Study marked as relevant” and “Study marked as irrelevant” do not have parameters.

In an embodiment, some subfilters may override other subfilters. For example, if a study has been marked as relevant, and the subfilter has been selected, then the relevant study will be retrieved, notwithstanding whether the study meets the criteria of the other selected subfilters.

FIGS. 3B and 3C show examples of potential configurations of subfilters and parameters used in accordance with an embodiment of the present invention. A system implementing the pre-fetch filter shown in FIG. 3B will retrieve all X-ray studies and images performed after Oct. 23, 2002 on Arvind Tarananth's knee and associated anatomies. Any study for Arvind marked as relevant will be retrieved, even if the study attributes do not match the other subfilters. Similarly, any study for Arvind marked as irrelevant will be ignored, even if the study attributes match the other subfilters.

A system implementing the pre-fetch filter shown in FIG. 3C will retrieve three most recent X-ray or CT scan studies performed by Dr. McCoy on Jeff Chu and Shrikant Deshpande. Any study marked as relevant for the patients will be retrieved, even if the study attributes do not match the other subfilters. Similarly, any study marked as irrelevant for the patients will be ignored, even if the study matches the other subfilters.

Turning back to FIG. 2, each filter may be independently determined at step 220. In other words, the subfilters and parameters corresponding to the filter may be defined locally and independently from other filters in the system. Alternatively, some subfilters and parameters may be global to some or all other filters. It may be preferable, for example, to have default subfilters and parameters that are global. By allowing for both global and local subfilter and parameter values, the pre-fetching technique exhibits improved flexibility and functionality.

At step 230, radiographic studies and images are pre-fetched corresponding to the filters determined at step 220. The studies and images may be retrieved from a long-term storage system 170, for example. Pre-fetched studies and images may be stored in on-line storage 130, or they may be distributed to appropriate locations on a network, such as an image manager 160. The pre-fetching step 230 may occur according to an automated schedule, or may be triggered by user intervention. The pre-fetching step 230 may employ all filters from step 220 in a batch job, or pre-fetching 230 may schedule different filters at various times, for example.

By designing pre-fetching to have improved flexibility and functionality, health care professionals and information technology professionals may tailor pre-fetching with more specificity, for example. Improved pre-fetching methods and systems may be configured to operate more accurately. Improved accuracy may translate to pre-fetching that is less under-inclusive and less over-inclusive. Improved accuracy may also translate to improved utilization of computer system resources and less waiting by radiologists and other clinicians, for example.

Thus, certain embodiments provide a pre-fetching system and method that better accommodate the needs of health care professionals. Certain embodiments provide a pre-fetching system and method that more accurately retrieves clinically relevant historical studies and images. Certain embodiments provide a pre-fetching system and method that consume less computer system resources and bandwidth. For example, certain embodiments reduce archive retrieves at pre-fetching time and at reading time. Certain embodiments provide a pre-fetching system and method with increased flexibility, functionality, and accuracy. Certain embodiments provide a pre-fetching system that allows different rules to be configured for different modalities. Certain embodiments provide a pre-fetching system and method that allow health care professionals to spend less time retrieving records.

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiment disclosed, but that the invention will include all embodiments falling within the scope of the appended claims.

1. A method of retrieving radiographic images comprising:
interfacing with a storage system containing radiographic images, some of said radiographic images comprising data representative of an image modality;
determining at least one filter corresponding to a filter modality, each of said at least one filter independently determinable from other said filters; and
pre-fetching at least one said radiographic image using said at least one filter, wherein said image modality of said at least one radiographic image corresponds to said filter modality.

2. The method of claim 1 wherein said at least one filter comprises at least one subfilter capable of differentiating said radiographic images based at least in part on attributes of said radiographic images.

3. The method of claim 2 wherein said at least one subfilter may be independently determinable from at least one other subfilter.

4. The method of claim 1 wherein said storage system comprises a long-term storage system.

5. The method of claim 1 wherein a picture archiving and communication system (PACS) facilitates at least one of said interfacing, determining, and pre-fetching steps.

6. The method of claim 1 wherein more than one of said at least one filter correspond to said filter modality, and wherein each of said at least one filter is independently determinable from other of said at least one filter.

7. The method of claim 1 wherein said at least one filter may be determined to differentiate clinically relevant images in said storage system.

8. A system for gathering radiographic images comprising:
an interface to an archive including images, at least some of said images including information representative of a modality; and
at least one filter capable of facilitating a selection of images corresponding to said modality, wherein said at least one filter is independently configurable from other filters.

9. The system of claim 8 wherein said at least one filter comprises at least one subfilter corresponding to attributes of said images, and said at least one filter may facilitate a selection of images corresponding to said attributes of said images.

10. The system of claim 9 wherein said at least one subfilter may be independently configurable from other of said subfilters.

11. The system of claim 8 further comprising a PACS capable of configuring said at least one filter.

12. The system of claim 8 further comprising a PACS capable of selecting said images from said archive.

13. The system of claim 8 further comprising an on-line image storage system capable of short-term storage of selected said images.

14. The system of claim 8 wherein said at least one filter may be automatedly used to select said images.

15. A computer readable storage medium including a set of instructions for a computer, the set of instructions comprising:
an interfacing routine for communicating with a storage system containing images, some of said images comprising data representative of a modality;
a filter recall routine for recalling at least one filter having parameters independently configurable from said parameters of other said at least one filter; and
a pre-fetching routine for retrieving said images from said storage system based at least in part on said modality using said at least one filter.

16. The set of instructions of claim 15 further comprising a scheduling routine for automatedly calling said pre-fetching routine.

17. The set of instructions of claim 15 wherein a picture archiving and communication system (PACS) facilitates execution of at least one of said interfacing, filter storage, and pre-fetching routines.

18. The set of instructions of claim 15 wherein said storage system includes a long-term archive.

19. The set of instructions of claim 15 wherein said parameters include at least one of modality, procedure, anatomy, reason for procedure, date, significance, and physician.

20. The set of instructions of claim 15 comprising a filter configuration routine for independently configuring said at least one filter.
